(19) United States
(12) Patent Application Publication
(10) Pub. No.: US 2025/0092573 A1
(43) Pub. Date: Mar. 20, 2025

(54) METHOD FOR PURIFYING GRAPHITE MATERIAL, METHOD FOR PURIFYING GRAPHITE CRUCIBLE BASED ON SILICON CARBIDE CRYSTAL GROWTH, AND METHOD FOR MANUFACTURING HIGH-PURITY SILICON CARBIDE

(71) Applicant: TAISIC MATERIALS CORP., TAOYUAN CITY (TW)

(72) Inventors: Dai-Liang MA, TAOYUAN CITY (TW); Bang-Ying YU, TAOYUAN CITY (TW); Bo-Cheng LIN, TAOYUAN CITY (TW)

(21) Appl. No.: 18/885,761

(22) Filed: Sep. 16, 2024

Related U.S. Application Data
(60) Provisional application No. 63/583,590, filed on Sep. 19, 2023.

(30) Foreign Application Priority Data
Jun. 28, 2024 (TW) 113124356

(51) Int. Cl. C30B 35/00; C01B 32/215; C30B 29/36

(52) U.S. Cl. CPC C30B 35/002; C01B 32/215; C30B 29/36

(57) ABSTRACT

Disclosed is a method for purifying a graphite material, which includes the following steps of: after placing the graphite material in a graphite crucible, placing the graphite crucible into a heating furnace; after vacuuming the heating furnace, filling the heating furnace with a protective atmosphere, and controlling a pressure in the heating furnace to be less than 5 Torr; and heating the graphite crucible, by a heater disposed in the heating furnace, to control a temperature of the graphite crucible to be at least higher than melting point temperatures of some metal impurities in the graphite material for a preset time period, so that the some metal impurities in the graphite material are volatilized or carbonized, and the graphite crucible is purified. Therefore, while the graphite material is purified under a condition with high vacuum, high temperature and low pressure, the graphite crucible is also purified.

### CROSS REFERENCE TO RELATED PRESENT DISCLOSURE

This application claims the priority benefit of Taiwan Patent Application Serial Number 113124356, filed on Jun. 28, 2024 and the benefit of U.S. Provisional Application No. 63/583,590, filed Sep. 19, 2023, the entire contents of which are hereby incorporated by reference herein.

### TECHNICAL FIELD

The present disclosure relates to a method for purifying a graphite material, a method for purifying a graphite crucible based on silicon carbide growth and a method for manufacturing high-purity silicon carbide, in particular to a method for purifying a graphite material, a method for purifying a graphite crucible based on silicon carbide growth and a method for manufacturing high-purity silicon carbide, which are performed under a condition with high vacuum, high temperature and low pressure.

### RELATED ART

Graphite has many advantages such as corrosion resistance, good electrical conductivity, good thermal conductivity, and high temperature resistance, so it has important application value in the fields of machinery, metallurgy, chemistry, electricity, aerospace and nuclear industry. The purity of graphite determines the usage characteristics and comprehensive performance of graphite materials. The higher the purity of graphite, the higher the application value of graphite.

At present, high-purity graphite is usually produced by hydrofluoric acid method and chloride roasting method, wherein in the hydrofluoric acid method, impurities in graphite, such as oxides and silicate minerals of potassium, sodium, magnesium, iron, calcium and aluminum, react with the hydrofluoric acid to generate water-soluble fluoride and volatile matters, thereby achieving the purpose of graphite purification; in the chlorination roasting method, chlorine is used to convert impurities in graphite into volatile matters to achieve the purpose of graphite purification. However, chlorine and hydrofluoric acid have strong corrosivity and toxicity, and the use of chlorine and hydrofluoric acid requires the use of proprietary equipment to purify graphite, which result in high costs for the production of high-purity graphite and involve environmental protection issues.

### SUMMARY

The embodiments of the present disclosure provide a method for purifying a graphite material, which can solve the problems of high production costs and involving environmental protection issues due to the strong corrosivity and toxicity of chlorine and hydrofluoric acid since the hydrofluoric acid method and the chlorination roasting method are used to purify graphite, and can be further derivatively applied to a method for purifying a graphite crucible based on silicon carbide growth and a method for manufacturing high-purity silicon carbide of the present disclosure.

In order to solve the above technical problems, the present disclosure is implemented as follows:

The present disclosure provides a method for purifying a graphite material, which includes the following steps: after placing a graphite material in a graphite crucible, placing the graphite crucible into a heating furnace; after vacuuming the heating furnace, filling the heating furnace with a protective atmosphere, and controlling a pressure in the heating furnace to be less than 5 Torr; and heating the graphite crucible, by a heater disposed in the heating furnace, to control a temperature of the graphite crucible to be at least higher than melting point temperatures of some of metal impurities in the graphite material, and maintaining the temperature of the graphite crucible for a preset time, so that the some of metal impurities in the graphite material are volatilized or carbonized, and the graphite crucible is purified.

The present disclosure provides a method for purifying a graphite crucible based on silicon carbide growth, which includes the following steps: providing a graphite crucible with a purity greater than 99.96%; after placing a silicon carbide raw material in a source area of the graphite crucible and fixing a seed on a crucible cover of the graphite crucible, placing the graphite crucible in a heating furnace; vacuuming the heating furnace, while heating the graphite crucible with a heater disposed in the heating furnace, and when a temperature of the graphite crucible is 1200° C. to 1400° C., filling a protective atmosphere into the heating furnace to make a pressure in the heating furnace rise to 5E5 times to 9.5E5 times a partial pressure of a silicon carbide atmosphere; and maintaining the pressure in the heating furnace at 5E5 times to 9.5E5 times the partial pressure of the silicon carbide atmosphere, while continuing to heat the graphite crucible with the heater, and when the temperature of the graphite crucible is 2000° C. to 2300° C., controlling the pressure of the graphite crucible to be reduced to between 0.5 Torr and 100 Torr, and maintaining the pressure of the graphite crucible and the temperature of the graphite crucible for a preset time, so that a silicon carbide crystal grows from the seed, and some of metal impurities in the graphite crucible are volatilized or carbonized to purify the graphite crucible.

The present disclosure provides a method for manufacturing high-purity silicon carbide, which includes the following steps: providing the graphite crucible purified by the method for purifying the graphite material of the present disclosure, or providing the graphite crucible purified by the method for purifying a graphite crucible based on silicon carbide growth of the present disclosure, wherein the purity of the graphite crucible is greater than or equal to 99.99%; after placing a silicon carbide raw material in a source area of the graphite crucible and fixing a seed on a crucible cover of the graphite crucible, placing the graphite crucible in a heating furnace; vacuuming the heating furnace, while heating the graphite crucible with a heater disposed in the heating furnace, and when a temperature of the graphite crucible is 1200° C. to 1400° C., filling a protective atmosphere into the heating furnace to make a pressure in the heating furnace rise to 5E5 times to 9.5E5 times a partial pressure of a silicon carbide atmosphere; and maintaining the pressure in the heating furnace at 5E5 times to 9.5E5 times the partial pressure of the silicon carbide atmosphere, while continuing to heat the graphite crucible with the heater, and when the temperature of the graphite crucible is a growth temperature, controlling the pressure of the graphite crucible to be reduced to between 0.5 Torr and 100 Torr, and maintaining the temperature of the graphite crucible and the pressure of the graphite crucible for a preset time, so that a silicon carbide crystal grows from the seed.

In the embodiments of the present disclosure, the method for purifying the graphite material does not use chlorine or hydrofluoric acid to purify the graphite, so it does not require the use of proprietary equipment and does not involve environmental protection issues. At the same time, the method for purifying the graphite material can be derivatively applied to the method for purifying the graphite crucible based on silicon carbide growth and the method for manufacturing high-purity silicon carbide of the present disclosure. In addition, in the method for purifying the graphite material and the method for purifying the graphite crucible based on silicon carbide growth of the embodiments of the present disclosure, while the graphite material is purified/silicon carbide crystal grows under the conditions of high vacuum, high temperature and low pressure, the graphite crucible is also purified. Besides, the purified graphite crucible obtained in the embodiments of the present disclosure (i.e., the high-purity graphite crucible, the purity of graphite crucible is greater than or equal to 99.99%) is used for the growth of silicon carbide crystal under the condition of high vacuum, high temperature and low pressure, so it can prevent impurities in the graphite crucible from escaping during the crystal growth process and forming heterogeneous nucleation points on the growth surface of the silicon carbide crystal, causing defects in the silicon carbide crystal, thereby improving the purity of the silicon carbide crystal.

### BRIEF DESCRIPTION OF THE DRAWINGS

Accompanying drawings described herein are intended to provide a further understanding of the present disclosure and form a part of the present disclosure, and exemplary embodiments of the present disclosure and descriptions thereof are intended to explain the present disclosure but are not intended to unduly limit the present disclosure. In the drawings:

FIG. 1 is a schematic structural diagram of purification equipment used in a method for purifying a graphite material of the present disclosure;

FIG. 2 is a method flow chart of a method for purifying a graphite material according to an embodiment of the present disclosure;

FIG. 3 is a method flow chart of a method for purifying a graphite material according to another embodiment of the present disclosure;

FIG. 4 is a schematic structural diagram of silicon carbide growth equipment used in a method for purifying a graphite crucible based on silicon carbide growth and a method for manufacturing high-purity silicon carbide of the present disclosure;

FIG. 5 is a method flow chart of a method for purifying a graphite crucible based on silicon carbide growth according to an embodiment of the present disclosure; and

FIG. 6 is a method flow chart of a method for manufacturing high-purity silicon carbide according to an embodiment of the present disclosure.

### DETAILED DESCRIPTION OF THE EMBODIMENTS

The embodiments of the present disclosure will be described below in conjunction with the relevant drawings. In the figures, the same reference numbers refer to the same or similar components or method flows.

It must be understood that the words “including”, “comprising” and the like used in this specification are used to indicate the existence of specific technical features, values, method steps, work processes, elements and/or components. However, it does not exclude that more technical features, values, method steps, work processes, elements, components, or any combination of the above can be added.

It must be understood that when an element is described as being “connected” or “coupled” to another element, it may be directly connected or coupled to another element, and intermediate elements therebetween may be present. In contrast, when an element is described as “directly connected” or “directly coupled” to another element, there is no intervening element therebetween.

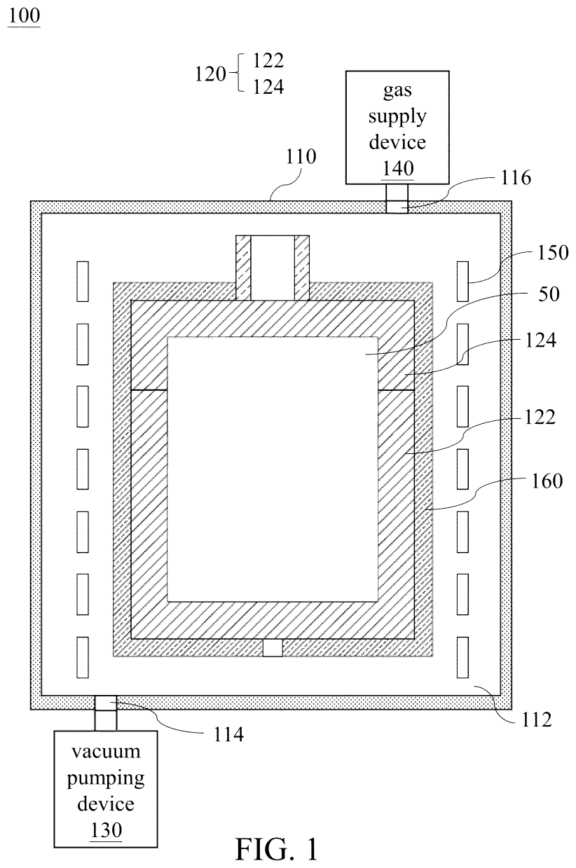

Please refer to FIG. 1, which is a schematic structural diagram of purification equipment used in a method for purifying a graphite material of the present disclosure. As shown in FIG. 1, the purification equipment 100 comprises a heating furnace 110, a graphite crucible 120, a vacuum pumping device 130, a gas supply device 140 and a heater 150. The heating furnace 110 has a first cavity 112 and is provided with a first gas port 114 and a second gas port 116. The first gas port 114 is configured to connect the vacuum pumping device 130, and the second gas port 116 is configured to connect the gas supply device 140. The graphite crucible 120 can be disposed in the heating furnace 110 and comprises a crucible body 122 and a crucible cover 124. The crucible cover 124 covers the crucible body 122 to form a second cavity 50. The graphite crucible 120 may be, but is not limited to, a graphite crucible with a diameter of 6 inches to 10 inches. The vacuum pumping device 130 and the gas supply device 140 can be disposed outside the heating furnace 110. The heater 150 can be disposed inside the heating furnace 110 and located on the periphery of the graphite crucible 120. The heater 150 may be a high frequency heater. For example, the heater 150 may be, but is not limited to, a heating coil. In addition, the purification equipment 100 may further comprise a thermal insulation material 160, which may be disposed outside the graphite crucible 120. The thermal insulation material 160 may be, but is not limited to, a porous heat-insulating carbon material to achieve the effect of temperature maintenance.

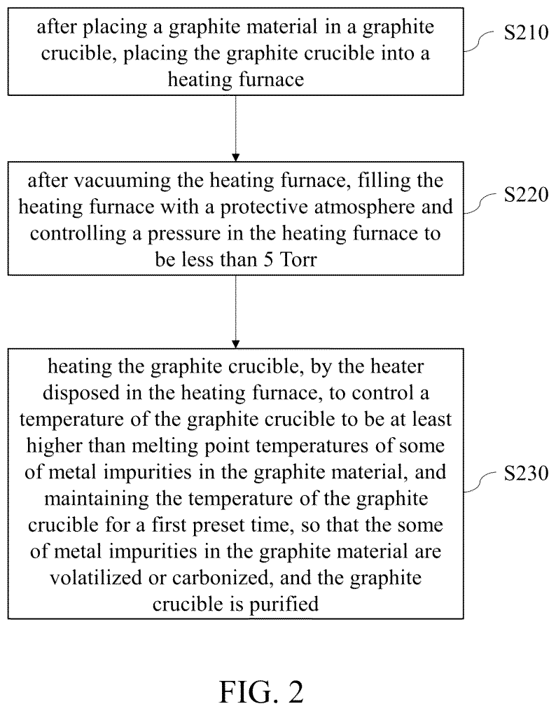

Please refer to FIG. 1 and FIG. 2. FIG. 2 is a method flow chart of a method for purifying a graphite material according to an embodiment of the present disclosure. The method for purifying the graphite material in FIG. 2 can be applied to the purification equipment 100 of FIG. 1. The method for purifying the graphite material in FIG. 2 comprises the following steps: after placing a graphite material in a graphite crucible 120, placing the graphite crucible 120 into a heating furnace 110 (step S210); after vacuuming the heating furnace 110, filling the heating furnace 110 with a protective atmosphere and controlling a pressure in the heating furnace 110 to be less than 5 Torr (step S220); and heating the graphite crucible 120, by the heater 150 disposed in the heating furnace 110, to control a temperature of the graphite crucible 120 to be at least higher than melting point temperatures of some of metal impurities in the graphite material, and maintaining the temperature of the graphite crucible 120 for a first preset time, so that the some of metal impurities in the graphite material are volatilized or carbonized, and the graphite crucible 120 is purified (step S230).

In step S210, the graphite material is first placed in the crucible body 122, and then the crucible cover 124 covers the crucible body 122; next, the graphite crucible 120 is placed in the heating furnace 110. The graphite material refers to an article made of graphite as the main material. For example, the graphite material may be, but is not limited to, a graphite paper, a graphite blanket, a graphite felt or a graphite wire. It should be noted that since the joint between the crucible cover 124 and the crucible body 122 is not sealed (that is, there is a gap (not shown) between the crucible cover 124 and the crucible body 122), the first cavity 112 of the heating furnace 110 is communicated with the second cavity 50 of the graphite crucible 120 when the graphite crucible 120 is placed in the heating furnace 110.

In step S220, the heating furnace 110 is vacuumized by the vacuum pumping device 130 through the first air port 114, and the first cavity 112 of the heating furnace 110 is communicated with the second cavity 50 of the graphite crucible 120, so the vacuum pumping device 130 can remove air and other impurities in the first cavity 112 of the heating furnace 110 and the second cavity 50 of the graphite crucible 120 through the first air port 114. The gas supply device 140 fills the heating furnace 110 with a protective atmosphere through the second gas port 116, and the first cavity 112 of the heating furnace 110 is communicated with the second cavity 50 of the graphite crucible 120, so the gas supply device 140 can fill the first cavity 112 of the heating furnace 110 and the second cavity 50 of the graphite crucible 120 with the protective atmosphere through the second gas port 116. The pressures in the first cavity 112 of the heating furnace 110 and the second cavity 50 of the graphite crucible 120 are controlled to be less than 5 Torr by the vacuum pumping device 130 and the gas supply device 140. The protective atmosphere comprises, but is not limited to, argon or helium, and the flow range of argon or helium can be controlled from 100 to 1000 sccm (standard cubic centimeter per minute).

In step S230, the temperature of the graphite crucible 120 is controlled by the heater 150 to be at least higher than the melting point temperatures of some metal impurities in the graphite material and lower than the melting point temperature of graphite, and the temperature of the graphite crucible 120 is maintained for the first preset time, so that the metal impurities with the relatively low melting point temperatures in the graphite material become gas due to high temperature and escape, and the metal impurities with the relatively high melting point temperatures in the graphite material become carbides in a carbon-rich (C-rich) environment. Since the graphite crucible 120 is a crucible made of graphite as the main material, the graphite crucible 120 has substantially the same type of metal impurities as the graphite material. Therefore, while the graphite material is purified, the graphite crucible 120 can also be purified. The metal impurities in the graphite material can be selected from the group consisting of titanium, vanadium, yttrium, iron, cobalt, nickel, molybdenum, chromium, aluminum and a combination thereof, but this embodiment is not intended to limit the present disclosure. For example, the metal impurities in the graphite material may further comprise manganese, copper, potassium or zinc. In addition, the first preset time may be, but is not limited to, 0.5 hours to 10 hours, and may be adjusted according to actual needs.

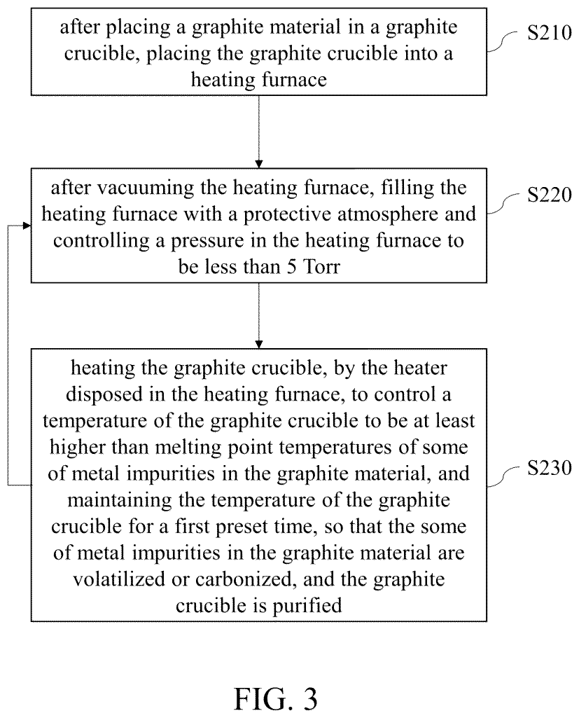

Please refer to FIG. 1 and FIG. 3. FIG. 3 is a method flow chart of a method for purifying a graphite material according to another embodiment of the present disclosure. The method for purifying the graphite material in FIG. 3 can be applied to the purification equipment 100 of FIG. 1. In order to further purify the graphite material and the graphite crucible 120, in addition to step S210 to step S230, the method for purifying the graphite material in FIG. 3 may further comprise: repeating step S220 and step S230 one or more times. The temperature of the graphite crucible 120 in the next time of step S230 may be greater than or equal to the temperature of the graphite crucible 120 in the previous time of step S230. In addition, the first preset time in the next time of step S230 may be greater than or equal to the first preset time in the previous time of step S230.

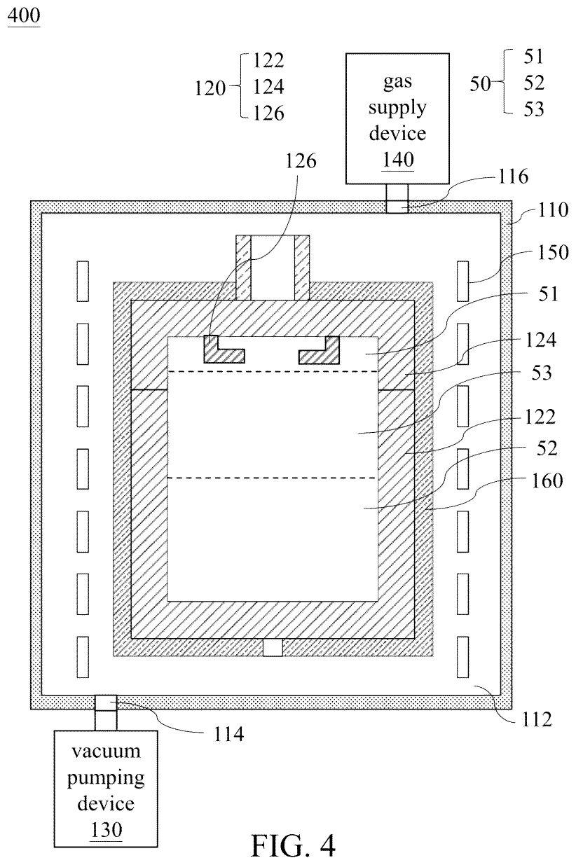

Please refer to FIG. 4, which is a schematic structural diagram of a silicon carbide growth equipment used in a method for purifying a graphite crucible based on silicon carbide growth and a method for manufacturing high-purity silicon carbide of the present disclosure. As shown in FIG. 4, the differences between the silicon carbide growth equipment 400 of FIG. 4 and the purification equipment 100 of FIG. 1 are that the crucible cover 124 of the graphite crucible 120 of FIG. 4 is equipped with a holder 12, and the second cavity 50 of the graphite crucible 120 of FIG. 4 has a seed area 51, a source area 52 and a growth area 53, wherein the area where the seed is placed in the graphite crucible 120 is defined as the seed area 51, the area where the silicon carbide raw material is placed in the graphite crucible 120 is defined as the source area 52, and the growth area 53 is provided between the seed area 51 and the source area 52, and is used as a growth area for the silicon carbide crystal. It should be noted that since the graphite crucible 120 used in the method for purifying the graphite material in the above embodiment can be reused in a method for purifying a graphite crucible based on silicon carbide growth and a method for manufacturing high-purity silicon carbide of the present disclosure, the crucible cover 124 of the graphite crucible 120 in the purification equipment 100 of FIG. 1 may also be equipped with the holder 126, but the holder 126 is not used in the method for purifying the graphite material. In other words, the purification equipment 100 of FIG. 1 can also be applied to silicon carbide crystal growth.

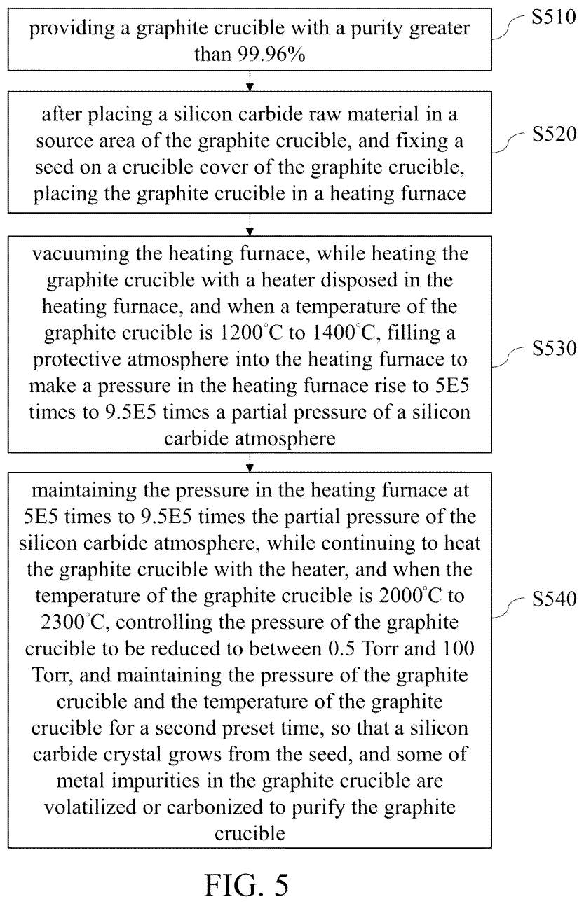

Please refer to FIG. 4 and FIG. 5. FIG. 5 is a method flow chart of a method for purifying a graphite crucible based on silicon carbide growth according to an embodiment of the present disclosure. The method for purifying the graphite crucible based on silicon carbide growth in FIG. 5 can be applied to the silicon carbide growth equipment 400 of FIG. 4. The method for purifying the graphite crucible based on silicon carbide growth in FIG. 5 comprises the following steps: providing a graphite crucible 120 with a purity greater than 99.96% (step S510); after placing a silicon carbide raw material in a source area 52 of the graphite crucible 120, and fixing a seed on a crucible cover 124 of the graphite crucible 120, placing the graphite crucible 120 in a heating furnace 110 (step S520); vacuuming the heating furnace 110, while heating the graphite crucible 120 with a heater 150 disposed in the heating furnace 110, and when a temperature of the graphite crucible 120 is 1200° C. to 1400° C., filling a protective atmosphere into the heating furnace 110 to make a pressure in the heating furnace 110 rise to 5E5 times to 9.5E5 times a partial pressure of a silicon carbide atmosphere (step S530); and maintaining the pressure in the heating furnace 110 at 5E5 times to 9.5E5 times the partial pressure of the silicon carbide atmosphere, while continuing to heat the graphite crucible 120 with the heater 150, and when the temperature of the graphite crucible 120 is 2000° C. to 2300° C., controlling the pressure of the graphite crucible 120 to be reduced to between 0.5 Torr and 100 Torr, and maintaining the pressure of the graphite crucible 120 and the temperature of the graphite crucible 120 for a second preset time, so that a silicon carbide crystal grows from the seed, and some of metal impurities in the graphite crucible 120 are volatilized or carbonized to purify the graphite crucible 120 (step S540).

In step S510, the graphite crucible 120 may be the graphite crucible purified in the method for purifying the graphite material of the present disclosure, but this embodiment is not intended to limit the present disclosure. For example, the graphite crucible 120 may be a brand new and unused graphite crucible.

In step S520, the silicon carbide raw material is placed in the source area 52 of the graphite crucible 120, the seed is fixed to the holder 126 configured on the crucible cover 124, and the crucible cover 124 covers the crucible body 122, and then the graphite crucible 120 is placed into the heating furnace 110. The silicon carbide raw material may be in the form of, but is not limited to, powder, granular, or block. The purity of the silicon carbide raw material is greater than 99.99%. The crystal phase of the silicon carbide raw material may be a phase or R phase. The seed may use, but is not limited to, silicon carbide. The diameter of the seed may be, but is not limited to, more than 4 inches. This embodiment is not intended to limit the present disclosure.

In step S530, the heating furnace 110 is vacuumed by the vacuum pumping device 130 through the first air port 114, and the first cavity 112 of the heating furnace 110 is communicated with the second cavity 50 of the graphite crucible 120, so the vacuum pumping device 130 can remove air and other impurities in the first cavity 112 of the heating furnace 110 and the second cavity 50 of the graphite crucible 120 through the first air port 114. The gas supply device 140 fills the heating furnace 110 with a protective atmosphere through the second gas port 116, and the first cavity 112 of the heating furnace 110 is communicated with the second cavity 50 of the graphite crucible 120, so the gas supply device 140 can fill the first cavity 112 of the heating furnace 110 and the second cavity 50 of the graphite crucible 120 with the protective atmosphere through the second gas port 116. Through the vacuum pumping device 130 and the gas supply device 140, the pressure in the first cavity 112 of the heating furnace 110 and the second cavity 50 of the graphite crucible 120 is controlled to rise to 5E5 to 9.5E5 times the partial pressure of the silicon carbide atmosphere (about 50 kPa to 95 kPa) when the temperature of the graphite crucible 120 is 1200° C. to 1400° C. When the temperature of the graphite crucible 120 is 1200° C. to 1400° C., the heating furnace 110 is filled with the protective atmosphere, so that the pressure in the heating furnace 110 rises to 5E5 times to 9.5E5 times the partial pressure of the silicon carbide atmosphere, ensuring that silicon carbide of the seed is not evaporated under this condition. The protective atmosphere comprises, but is not limited to, argon or helium, and the flow range of argon or helium can be controlled from 100 sccm to 1000 sccm.

In step S540, the pressure in the heating furnace 110/the pressure of the graphite crucible 120 is between 0.5 Torr and 100 Torr, the temperature of the graphite crucible 120 is 2000° C. to 2300° C., and the pressure of the graphite crucible 120 and the temperature of the graphite crucible 120 are maintained for the second preset time, so the silicon carbide raw material can be sublimated and vaporized after being heated and deposited in the form of gas phase molecules on the crystal surface of the seed (that is, the silicon carbide crystal grows from the seed), and at the same time, the metal impurities with the relatively low melting point temperatures in the graphite crucible 120 become gas and escape due to the high temperature, and the metal impurities with the relatively high melting point temperatures in the graphite crucible 120 become carbides in a carbon-rich environment. Therefore, while the silicon carbide crystal grows, the graphite crucible 120 can also be purified. The second preset time may be, but is not limited to, 100 hours to 300 hours, and may be adjusted according to actual needs.

In addition, step S540 may comprise: heating the graphite crucible 120 by the heater 150 to control a top temperature of the graphite crucible 120 to be 2000° C. to 2300° C. and a bottom temperature of the graphite crucible 120 to be higher than the top temperature of the graphite crucible 120, and maintaining the top temperature of the graphite crucible 120 and the bottom temperature of the graphite crucible 120 for the second preset time, so that the silicon carbide crystal grows from the seed and some metal impurities in the graphite crucible 120 are volatilized or carbonized, thereby purifying the graphite crucible 120. In other words, the temperature gradient of the graphite crucible 120 can be controlled by the heater 150.

It should be noted that after the silicon carbide crystal growth is completed, the purified graphite crucible 120 in step S540 can be used again in the method for purifying the graphite crucible based on silicon carbide growth of the present disclosure (that is, the purified graphite crucible 120 in step S540 can be reused), thereby further improving the purity of the graphite crucible 120.

Please refer to Table 1, which is a comparison table of metal impurity concentration and purity of the graphite crucible before and after using the method for purifying the graphite crucible based on silicon carbide growth of the present disclosure, wherein the graphite crucible before using the method for purifying the graphite crucible based on silicon carbide growth of the present disclosure is a brand new and unused graphite crucible, and the graphite crucible after using the method for purifying the graphite crucible based on silicon carbide growth of the present disclosure refers to a graphite crucible after four times of silicon carbide crystal growth. It can be seen from Table 1 that the metal impurity concentration of the graphite crucible before using the method for purifying the graphite crucible based on silicon carbide growth of the present disclosure is 128.8 ppm (parts per million), and the purity of the graphite crucible is 99.96%; the metal impurity concentration of the graphite crucible after using the method for purifying the graphite crucible based on silicon carbide growth of the present disclosure is 10 ppm, and the purity of the graphite crucible is 99.99%. Therefore, it can be seen that the method for purifying the graphite crucible based on silicon carbide growth of the present disclosure can purify the graphite crucible while growing the silicon carbide crystal.

TABLE 1

| | Graphite crucible before using | Graphite crucible after using |
|---|---|---|
| | a method for purifying a | a method for purifying a |
| | graphite crucible based on | graphite crucible based on |
| | silicon carbide growth of | silicon carbide growth of |
| | the present disclosure | the present disclosure |
| Metal impurity | 128.8 | 10 |
| concentration (ppm) | | |
| Purity (%) | 99.96 | 99.99 |

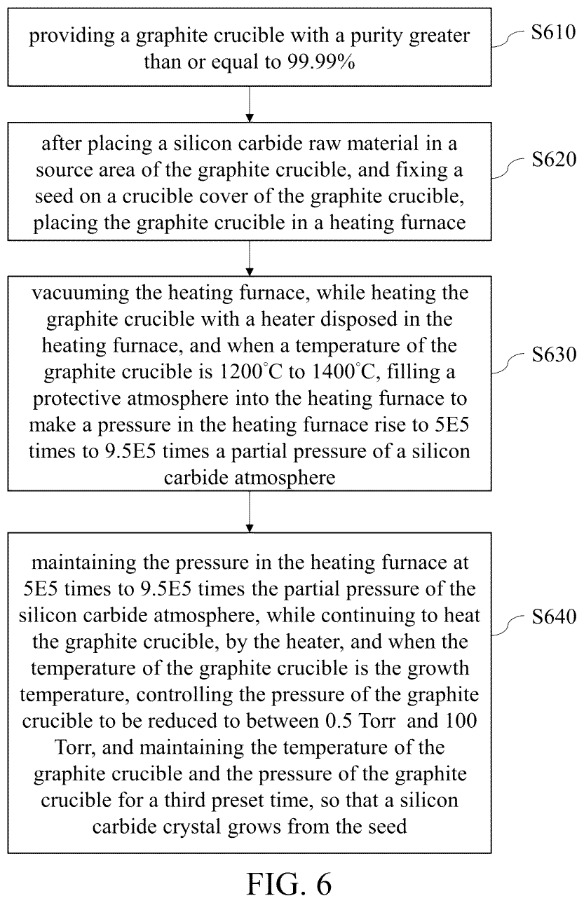

Please refer to FIG. 4 and FIG. 6. FIG. 6 is a method flow chart of a method for manufacturing high-purity silicon carbide according to an embodiment of the present disclosure. The method for manufacturing high-purity silicon carbide in FIG. 6 can be applied to the silicon carbide growth equipment 400 of FIG. 4. The method for manufacturing high-purity silicon carbide in FIG. 6 comprises the following steps: providing a graphite crucible 120 with a purity greater than or equal to 99.99% (step S610); after placing a silicon carbide raw material in a source area 52 of the graphite crucible 120, and fixing a seed on a crucible cover 124 of the graphite crucible 120, placing the graphite crucible 120 in a heating furnace 110 (step S620); vacuuming the heating furnace 110, while heating the graphite crucible 120 with a heater 150 disposed in the heating furnace 110, and when a temperature of the graphite crucible 120 is 1200° C. to 1400° C., filling a protective atmosphere into the heating furnace 110 to make a pressure in the heating furnace 110 rise to 5E5 times to 9.5E5 times a partial pressure of a silicon carbide atmosphere (step S630); and maintaining the pressure in the heating furnace 110 at 5E5 times to 9.5E5 times the partial pressure of the silicon carbide atmosphere, while continuing to heat the graphite crucible 120, by the heater 150, and when the temperature of the graphite crucible 120 is the growth temperature, controlling the pressure of the graphite crucible 120 to be reduced to between 0.5 Torr and 100 Torr, and maintaining the temperature of the graphite crucible 120 and the pressure of the graphite crucible 120 for a third preset time, so that a silicon carbide crystal grows from the seed (step S640).

In step S610, the graphite crucible 120 can be a graphite crucible 120 purified in the method for purifying the graphite material of the present disclosure or the method for purifying the graphite crucible based on silicon carbide growth of the present disclosure, but this embodiment is not intended to limit the present disclosure. For example, the graphite crucible 120 may be a brand new and unused graphite crucible.

The implementation details of step S620 and step S520 are the same, and the implementation details of step S630 and step S530 are the same, so they will not be described again here.

In step S640, the pressure in the heating furnace 110/the pressure of the graphite crucible 120 is between 0.5 Torr and 100 Torr, the temperature of the graphite crucible 120 is the growth temperature, and the pressure of the graphite crucible 120 and the temperature of the graphite crucible 120 are maintained for the third preset times, so the silicon carbide raw material can be sublimated and vaporized after being heated and deposited in the form of gas phase molecules on the crystal surface of the seed. The crystal growth temperature may be, but is not limited to, 2050° C. to 2500° C., and the third preset time may be, but is not limited to, 20 hours to 100 hours. However, this embodiment is not used to limit the present disclosure. The actual growth temperature and the third preset time can be adjusted according to actual needs.

In addition, step S640 may comprise: heating the graphite crucible 120 by the heater 150 to control a top temperature of the graphite crucible 120 to be the growth temperature and a bottom temperature of the graphite crucible 120 to be higher than the top temperature of the graphite crucible 120, and maintaining the top temperature of the graphite crucible 120 and the bottom temperature of the graphite crucible 120 for the third preset time, so that the silicon carbide crystal grows from the seed. In other words, the temperature gradient of the graphite crucible 120 can be controlled by the heater 150.

Please refer to Table 2, which is a comparison table of the purity of the graphite crucibles before and after using the method for purifying the graphite crucible based on silicon carbide growth of the present disclosure, and the purity of silicon carbide crystal grown by the graphite crucibles before and after using the method for purifying the graphite crucible based on silicon carbide growth of the present disclosure used in the method for manufacturing high-purity silicon carbide in FIG. 6, wherein the graphite crucible before using the method for purifying the graphite crucible based on silicon carbide growth of the present disclosure is a brand new and unused graphite crucible, and the purity of the graphite crucible is 99.987%; the graphite crucible after using the method for purifying the graphite crucible based on silicon carbide growth of the present disclosure refers to a graphite crucible after one time of silicon carbide crystal growth, and the purity of the graphite crucible is 99.995%. It can be seen from Table 2 that the purity of the silicon carbide crystal grown by the graphite crucible before using the method for purifying the graphite crucible based on silicon carbide growth of the present disclosure used in the method for manufacturing high-purity silicon carbide in FIG. 6 is 99.9984% (i.e., 4N), and the purity of the silicon carbide crystal grown by the graphite crucible after using the method for purifying the graphite crucible based on silicon carbide growth of the present disclosure used in the method for manufacturing high-purity silicon carbide in FIG. 6 is 99.99959% (i.e., 5N). Therefore, it can be seen that using high-purity graphite crucibles to grow the silicon carbide crystal under the condition of high vacuum, high temperature and low pressure can improve the purity of silicon carbide crystal, and the purity of silicon carbide crystal is one order higher than the purity of graphite crucible (that is, the impurity concentration of silicon carbide crystal is one order smaller than the impurity concentration of graphite crucible).

TABLE 2

| | Graphite crucible before using | Graphite crucible after using |
|---|---|---|
| | a method for purifying a | a method for purifying a |
| | graphite crucible based on | graphite crucible based on |
| | silicon carbide growth of | silicon carbide growth of |
| | the present disclosure | the present disclosure |
| Purity of graphite crucible (%) | 99.987 | 99.995 |
| Purity of the silicon carbide | 99.9984 | 99.99959 |
| crystal grown by the method | | |
| for manufacturing high-purity | | |
| silicon carbide in FIG. 6 (%) | | |

To sum up, in the embodiments of the present disclosure, the method for purifying the graphite material does not use chlorine or hydrofluoric acid to purify the graphite, so it does not require the use of proprietary equipment and does not involve environmental protection issues. At the same time, the method for purifying the graphite material can be derivatively applied to the method for purifying the graphite crucible based on silicon carbide growth and the method for manufacturing high-purity silicon carbide of the present disclosure. In addition, in the method for purifying the graphite material and the method for purifying the graphite crucible based on silicon carbide growth of the embodiments of the present disclosure, while the graphite material is purified/silicon carbide crystal grows under the conditions of high vacuum, high temperature and low pressure, the graphite crucible is also purified. Besides, the purified graphite crucible obtained in the embodiments of the present disclosure (i.e., the high-purity graphite crucible, the purity of graphite crucible is greater than or equal to 99.99%) is used for the growth of silicon carbide crystal under the condition of high vacuum, high temperature and low pressure, so it can prevent impurities in the graphite crucible from escaping during the crystal growth process and forming heterogeneous nucleation points on the growth surface of the silicon carbide crystal, causing defects in the silicon carbide crystal, thereby improving the purity of the silicon carbide crystal.

While the present disclosure is disclosed in the foregoing embodiments, it should be noted that these descriptions are not intended to limit the present disclosure. On the contrary, the present disclosure covers modifications and equivalent arrangements obvious to those skilled in the art. Therefore, the scope of the claims must be interpreted in the broadest manner to comprise all obvious modifications and equivalent arrangements.

What is claimed is:

1. A method for purifying a graphite material, comprising the following steps:
(a) after placing a graphite material in a graphite crucible, placing the graphite crucible into a heating furnace;
(b) after vacuuming the heating furnace, filling the heating furnace with a protective atmosphere, and controlling a pressure in the heating furnace to be less than 5 Torr; and
(c) heating the graphite crucible, by a heater disposed in the heating furnace, to control a temperature of the graphite crucible to be at least higher than melting point temperatures of some of metal impurities in the graphite material, and maintaining the temperature of the graphite crucible for a preset time, so that the some of metal impurities in the graphite material are volatilized or carbonized, and the graphite crucible is purified.

2. The method for purifying the graphite material according to claim 1, wherein the protective atmosphere comprises argon or helium.

3. The method for purifying the graphite material according to claim 1, wherein the graphite material is a graphite paper, a graphite blanket, a graphite felt or a graphite wire.

4. The method for purifying the graphite material according to claim 1, wherein the preset time is 0.5 hours to 10 hours.

5. The method for purifying the graphite material according to claim 1, wherein the heater comprises a heating coil disposed around the graphite crucible.

6. The method for purifying the graphite material according to claim 1, wherein the metal impurities are selected from the group consisting of titanium, vanadium, yttrium, iron, cobalt, nickel, molybdenum, chromium, aluminum and a combination thereof.

7. The method for purifying the graphite material according to claim 1, further comprising: repeating step (b) and step (c) one or more times, wherein a temperature of the graphite crucible in the next time of step (c) is greater than or equal to a temperature of the graphite crucible in the previous time of step (c).

8. A method for purifying a graphite crucible based on silicon carbide growth, comprising the following steps:
(i) providing a graphite crucible with a purity greater than 99.96%;
(ii) after placing a silicon carbide raw material in a source area of the graphite crucible and fixing a seed on a crucible cover of the graphite crucible, placing the graphite crucible in a heating furnace;
(iii) vacuuming the heating furnace, while heating the graphite crucible with a heater disposed in the heating furnace, and when a temperature of the graphite crucible is 1200° C. to 1400° C., filling a protective atmosphere into the heating furnace to make a pressure in the heating furnace rise to 5E5 times to 9.5E5 times a partial pressure of a silicon carbide atmosphere; and
(iv) maintaining the pressure in the heating furnace at 5E5 times to 9.5E5 times the partial pressure of the silicon carbide atmosphere, while continuing to heat the graphite crucible with the heater, and when the temperature of the graphite crucible is 2000° C. to 2300° C., controlling the pressure of the graphite crucible to be reduced to between 0.5 Torr and 100 Torr, and maintaining the pressure of the graphite crucible and the temperature of the graphite crucible for a preset time, so that a silicon carbide crystal grows from the seed, and some of metal impurities in the graphite crucible are volatilized or carbonized to purify the graphite crucible.

9. The method for purifying the graphite crucible based on silicon carbide growth according to claim 8, wherein the protective atmosphere comprises argon or helium.

10. The method for purifying the graphite crucible based on silicon carbide growth according to claim 8, wherein the preset time is 100 hours to 300 hours.

11. The method for purifying the graphite crucible based on silicon carbide growth according to claim 8, wherein step (iv) further comprises:
heating the graphite crucible, by the heater, to control a top temperature of the graphite crucible to be 2000° C. to 2300° C. and a bottom temperature of the graphite crucible to be higher than the top temperature of the graphite crucible, and maintaining the top temperature of the graphite crucible and the bottom temperature of the graphite crucible for the preset time, so that the silicon carbide crystal grow from the seed, and the some of metal impurities in the graphite crucible are volatilized or carbonized to purify the graphite crucible.

12. A method for manufacturing high-purity silicon carbide, comprising the following steps:
(I) providing the graphite crucible purified by the method for purifying the graphite crucible based on silicon carbide crystal growth according to claim 8, wherein the purity of the graphite crucible is greater than or equal to 99.99%;
(II) after placing a silicon carbide raw material in a source area of the graphite crucible and fixing a seed on a crucible cover of the graphite crucible, placing the graphite crucible in a heating furnace;
(III) vacuuming the heating furnace, while heating the graphite crucible with a heater disposed in the heating furnace, and when a temperature of the graphite crucible is 1200° C. to 1400° C., filling a protective atmosphere into the heating furnace to make a pressure in the heating furnace rise to 5E5 times to 9.5E5 times a partial pressure of a silicon carbide atmosphere; and
(IV) maintaining the pressure in the heating furnace at 5E5 times to 9.5E5 times the partial pressure of the silicon carbide atmosphere, while continuing to heat the graphite crucible with the heater, and when the temperature of the graphite crucible is a growth temperature, controlling the pressure of the graphite crucible to be reduced to between 0.5 Torr and 100 Torr, and maintaining the temperature of the graphite crucible and the pressure of the graphite crucible for a preset time, so that a silicon carbide crystal grows from the seed.

13. The method for manufacturing high-purity silicon carbide according to claim 12, wherein the protective atmosphere comprises argon or helium.

14. The method for manufacturing high-purity silicon carbide according to claim 12, wherein the preset time is 20 hours to 100 hours.

15. The method for manufacturing high-purity silicon carbide according to claim 12, wherein the growth temperature is 2050° C. to 2500° C.

16. The method for manufacturing high-purity silicon carbide according to claim 12, wherein the step (IV) further comprises:
heating the graphite crucible, by the heater, to control a top temperature of the graphite crucible to be the growth temperature and a bottom temperature of the graphite crucible to be higher than the top temperature of the graphite crucible, and maintaining the top temperature of the graphite crucible and the bottom temperature of the graphite crucible for the preset time, so that the silicon carbide crystal grows from the seed.
